(19) United States
(12) Patent Application Publication
(10) Pub. No.: US 2025/0133690 A1
(43) Pub. Date: Apr. 24, 2025

(54) POWER SUPPLY POWER SHARING ADJUSTMENT IN AN INFORMATION PROCESSING SYSTEM

(71) Applicant: HEWLETT PACKARD ENTERPRISE DEVELOPMENT LP, Spring, TX (US)

(72) Inventors: Stephen Ejner Horvath, Roseville, CA (US); Chadi Farid Theodossy, Rocklin, CA (US); Alexander James Hartigan, Roseville, CA (US)

(21) Appl. No.: 18/489,277

(22) Filed: Oct. 18, 2023

(51) Int. Cl. H05K 7/20; G06F 1/20

(52) U.S. Cl. CPC H05K 7/2019; G06F 1/20

(57) ABSTRACT

An information processing system may comprise an electronic circuit comprising a primary circuit board of the information processing system, at least two power supplies providing electrical energy to the electronic circuit according to a power sharing ratio, with each power supply being cooled by a set of fans, and a controller, coupled to the set of power supplies and the set of fans. The controller detects a failure of one of the fans and adjusts the power sharing ratio from a default ratio to an adjusted ratio in response to detecting the failure of the one fan.

### INTRODUCTION

Many information processing systems, such as servers, network switches, and other networking devices, typically include processing circuits for performing various operations, power supplies for supplying electrical energy to the processing circuits, and cooling mechanisms, such as cooling fans, for cooling the ambient air temperature around the power supplies as well as, in many cases, the processing circuits. In some of these systems, multiple power supplies are provided (usually two, but occasionally more) and the power supplies are configured to operate in a redundant power supply configuration, which means that if one of the power supplies fails, the remaining functional power supply (or power supplies) is (are) capable of supplying all of the power needed by the system notwithstanding the loss of the failed power supply. Thus, the redundant configuration can allow for the system to continue operating even after a power supply failure. In addition, in some information processing systems, the fans are also provided in a redundant configuration, meaning that more fans are provided than are strictly needed so that the system can continue to operate even after the failure of one fan.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operation. In the drawings:

FIG. 1 is a block diagram illustrating an example information processing system.

FIG. 2 is a block diagram conceptually illustrating a system chassis comprising an information processing system in a first arrangement.

FIG. 3A shows an operational state for the system chassis in FIG. 2.

FIG. 3B shows another operational state for the system chassis in FIG. 2.

FIG. 3C shows another operational state for the system chassis in FIG. 2.

FIG. 4 is a block diagram conceptually illustrating a system chassis comprising an information system comprising a system chassis in a second arrangement.

FIG. 5 is a block diagram conceptually illustrating a system chassis comprising an information system comprising a system chassis in a third arrangement.

FIG. 6A is a block diagram conceptually illustrating another system chassis comprising an information processing system in an operational state.

FIG. 6B shows another operational state for the system chassis in FIG. 6A. comprising an information processing system in another operational state.

FIG. 7A is a block diagram conceptually illustrating another system chassis comprising an information processing system in an operational state.

FIG. 7B shows another operational state for the system chassis in FIG. 7A.

FIG. 7C shows another operational state for the system chassis in FIG. 7A.

FIG. 7D shows another operational state for the system chassis in FIG. 7A.

FIG. 8A is a block diagram conceptually illustrating another system chassis comprising an information processing system in an operational state.

FIG. 8B shows another operational state for the system chassis in FIG. 8A.

FIG. 8C shows another operational state for the system chassis in FIG. 8A.

FIG. 9A is a block diagram conceptually illustrating another system chassis comprising an information processing system in an operational state.

FIG. 9B shows another operational state for the system chassis in FIG. 9A.

FIG. 9C shows another operational state for the system chassis in FIG. 9A.

FIG. 10 is a process flow diagram illustrating an example process for power supply power sharing adjustment in an information processing system.

FIG. 11 is a process flow diagram illustrating another example process for power supply power sharing adjustment in an information processing system.

FIG. 12 illustrates an example non-transitory machine readable medium storing example power supply control instructions.

### DETAILED DESCRIPTION

In some information processing systems, such as servers, network switches, and other networking devices, that utilize a redundant power supply configuration, the power supplies are configured such that during normal operation each of the power supplies provides a portion of the electrical energy needed by the system. This may be referred to hereinafter as a redundant configuration with power sharing. Generally, in such systems the power demand is shared equally among all the power supplies.

In addition, in some systems with redundant power supplies, the fans are also arranged with some redundancy such that each of the power supplies continues to receive cooling from at least one fan notwithstanding any given fan failing. For example, the fans may be arranged such that each power supply may receive cooling from two or more fans.

Generally, redundant information processing systems are not usually designed to operate for a long period of time after the failure of a component. Instead, many redundant information processing systems are designed to continue operating after a failure for a limited time, which is generally long enough to allow for the failed component to be replaced. In particular, if a fan fails, the amount of cooling provided to one or more of the power supplies may be reduced significantly, and although the power supplies may be capable of operating with such reduced cooling in the short term (because the fans are in a redundant configuration), long term operation under such conditions may increase the risk of a power supply failing and/or cause diminished system performance. Thus, long term operation with a failed fan is generally not feasible even in a redundant system, and instead it is generally desired to replace the failed fan relatively quickly. In some information processing systems, such replacement of the failed fan is relatively easy because the cooling fans are mounted to a chassis used to enclose the electronic system in such a way as to make them removable and replaceable, referred to as a removable modular redundant system. Additionally, the failed cooling fan can often be replaced in the near term while the electronic system remains operational.

However, in some information processing systems, replacement of a failed fan may be more difficult because the cooling fans are mounted to the chassis in a fixed manner preventing them from being easily removed and replaced. Such systems are becoming more common as electronic systems become more space and cost constrained, and they may be referred to as fixed redundant systems. In such systems, when a cooling fan fails, instead of removing and replacing the failed component, the entire electronic system may need to be replaced. Unlike replacing a single fan which can often be done while the system remains operational, or with only a relatively brief downtime, replacing the entire system generally requires more significant downtime. Moreover, because the system is not intended to operate for long periods of time in redundant mode, a user may not be able to wait for a convenient time (such as scheduled downtime) to perform the replacement. As a result, even with the presence of redundancy, unplanned downtime is more likely to occur. Fixed redundant systems would thus benefit from a mechanism that can extend the amount of time that the system can continue to safely operate after a fan failure and otherwise improve the operational reliability of the power supplies, and thus provide an opportunity to more easily schedule downtime at timings that are less disruptive.

Thus, the present disclosure introduces a failover procedure for an information processing system comprising power supplies operating in a redundant configuration with power sharing, wherein the failover procedure is executed in response to the failure of a fan and comprises adjusting a power sharing ratio between the power supplies based on the fan failure. The power sharing ratio reflects the proportional amounts of electrical energy supplied to the information processing system by the power supplies. For example, if there are two power supplies each supplying half of the total power to the system, the power sharing ratio is 50:50. The power sharing ratio may be adjusted away from a default ratio based on the fan failure. In particular, the adjusted power sharing ratio may be one in which the power supply associated with the failed fan has a lower proportional contribution to the overall power supply, whereas the other power supply (or power supplies) that is (are) still receiving full cooling have higher proportional contribution(s) to the overall power supply. For example, if two power supplies are present and a fan failure occurs, the adjusted power sharing ratio may be something like 33:67 with the power supply associated with the failed fan supplying 33% of the total power and the other power supply supplying the remaining 67%.

More specifically, as part of normal operation of the electronic system, cooling is provided to a set of two or more power supplies in an electronic assembly with each of the power supplies supplying a default proportional amount of electrical energy to the electronic processing circuit. In some examples, the default proportional amount for the power supplies comprises an equal distribution of power. The cooling is provided to the power supplies by a set of multiple fans arranged such that each of the power supplies receives cooling from two or more cooling fans. The operation of the cooling fans is monitored to determine if the cooling fans are operating properly. If one of the cooling fans is not operating properly, this is deemed a failure of the fan and the proportional amount of electrical energy supplied to the system from each of the power supplies is adjusted to account for the cooling fan that is not operating properly. For example, if one of the cooling fans that provides cooling to a first power supply is not operating properly, the amount of electrical energy supplied by the first power supply is reduced while the amount supplied by the remaining power supplies is increased.

As a result of this adjustment in the power sharing ratio, the power supply that is receiving less cooling (due to the fan failure) will generate less heat (due to assuming a reduced load), and therefore that power supply is more likely to remain within desired temperature limits notwithstanding the fan failure. Moreover, although the other power supply may generate more heat (due to assuming a heavier load), it receives full cooling and thus should be able to also remain within desired temperature limits. Generally, one of the reasons conventional systems need to be replaced relatively soon after a fan failure is that a power supply may be capable of operating outside temperature limits for a limited amount of time, but when operated in this manner for an extended period of time it may be damaged or lose reliability. However, because the invention allows all of the power supplies to remain within desired temperature limits after the fan failure, such damage or loss in reliability may not occur or may take much longer to occur than in conventional systems. Accordingly, the system may be capable of continuing to operate after a fan failure without risking damage or loss in reliability for a longer period of time than would otherwise be possible in a conventional system. In some cases, the system may even be capable of continued operation in this state indefinitely, thus obviating the need to replace the entire system. Moreover, even if replacement is needed, the replacement does not need to occur as quickly as it would in a conventional system because the system can continue operating safely for a longer period of time, and therefore it may be easier to schedule the replacement at a convenient timing with less disruption.

Turning now to the figures, various devices, systems, and methods in accordance with aspects of the present disclosure will be described.

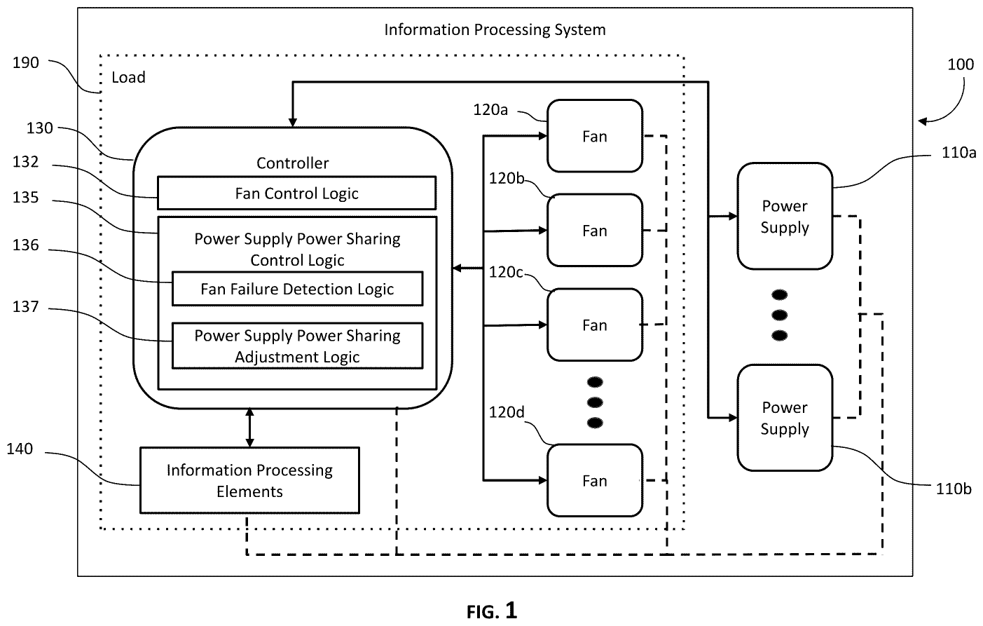

FIG. 1 is a block diagram illustrating an example information processing system 100. It should be understood that FIG. 1 is not intended to illustrate specific implementations of the illustrated components, and that implementations of information processing system 100 may have different numbers and arrangements of the illustrated components and may also include other elements that are not illustrated.

As shown in FIG. 1, information processing system 100 includes N power supplies 110 where N is any integer equal to or greater than two (power supplies 110a and 110b are shown as examples in FIG. 1), M fans 120 where M is any integer equal to or greater than four (fans 120a-120d are shown as examples in FIG. 1), a controller 130, and information processing elements 140. Power supplies 110 are electrically coupled (shown as dashed lines) to each of fans 120, controller 130, and information processing elements 140 in order to supply electrical energy. The fans 120, controller 130, and information processing elements 140 comprise the electrical load 190 (shown as a dotted line box) to which the power supplies 110 provide electrical energy. Controller 130 is communicatively coupled to the information processing elements 140 as well as each of the fans 120 and each of the power supplies 110. In one example implementation, information processing system 100 comprises two power supplies 110 (i.e., N=2) and four fans 120 (i.e., M=4). In other implementations, additional fans 120 and/or additional power supplies 110 may be used.

Power supplies 110 are configured to operate as redundant power supplies with power sharing with each of power supplies 110 providing a portion of the electrical energy required to operate the information processing system 100 based on a power sharing ratio determined, for instance, by the controller 130. The power sharing ratio may be different depending on different operating conditions. For example, the power sharing ratio for two power supplies 110-a and 110-b may be 50:50 (with respect to the order of reference numbers) during normal operation. In other words, each of the two power supplies provides 50 percent of the electrical energy for the system. The power sharing ratio used during normal operation may be referred to as the default ratio. In some examples, a different power sharing ratio, other than 50:50, may be used as the default ratio based on, for instance, performance characteristics of the power supplies. Examples of power supplies that may be used as redundant power supplies with power sharing include, but are not limited to, a switched mode power supply (SMPS), a series regulated linear power supply, a shunt regulated linear power supply, and the like.

As shown in FIG. 1, power supplies 110 are configured to provide a single direct current (DC) voltage, such as 12 volts, to each of fans 120, controller 130, and information processing elements 140 as part of supplying electrical energy. In some examples, power supplies 110 may be configured to provide more than one DC voltage through additional electrical power connections. For instance, power supplies 110 may be configured to provide 12 volts and 5 volts to information processing elements 140. In some examples, one or more additional sets of power supplies may be included in information processing system 100, each set of power supplies configured to provide electrical energy using a different DC voltage. For instance, three separate sets of power supplies, supplying 12 volts, 5 volts, and 3.3 volts, may be included. Notably, only one set of power supplies 110 is shown here to simplify the drawing. Moreover, although the various illustrated components are shown as connected to the same power supply connection, this is just for ease of illustration and these components do not all necessarily have to be connected to the same power supply connection.

In some examples, power supplies 110 may provide electrical energy to other components that are external to the information processing system 100, as shown in FIG. 1. For example, power supplies 110 may provide electrical energy to devices communicating with information system 100 using a network protocol (e.g., power over ethernet (POE)). Power supplies 110 may also provide electrical energy to one or more removable devices, such as hard disk drives, or network interfaces, that are electrically coupled to information processing system 100 and mechanically coupled to the housing or chassis used for information processing system 100. Although not illustrated, if such additional devices are present and drawing power from the power supplies 110, they may be considered as part of the load 190.

Fans 120 are configured to provide cooling to the other electrical and electronic components used in information processing system 100, including the information processing elements 140, the controller 130, and the power supplies 110. The fans 120 provide cooling by creating air flow over and around the electrical and electronic components. The air flow is generated by taking in, or pulling in, air at one side of the fan and exhaling, or pushing, air out at another side of the fan. Various mechanical configurations for fans 120 may be used. For example, air flow may enter at first side of the fan and exit at a side opposite the first side in a direction perpendicular to the rotational axis of the blades of the fan. Further, the fans 120 may be horizontally or vertically oriented with respect to the housing or chassis used for information processing system 100, with the air flow moving parallel or perpendicular to the rotational axis of the blades.

The operation of the fans 120 can be controlled and/or monitored by controller 130, depending on the type of fan that is used. For example, fans 120 may be two wire fans (i.e., a power wire and a ground wire) that operate at one or more speeds depending on the power (i.e., voltage) that is applied. Controller 130 controls these fans by providing a voltage to the fans via the power wire and monitors the fans by measuring the amount of current provided in the power wire when the fans are operating. Two wire fans may be single speed, having only one voltage value that can be provided, or may be multi-speed, having a range of voltage values that can be provided. In another example, fans 120 may be three wire fans that include a power and ground wire along with a tachometer signal wire that provides a signal with frequency proportional to speed back to controller 130. Controller 130 controls these fans in the same manner as the two wire fans above but can monitor the operation of the fans by comparing the value from the tachometer signal to the expected speed of the fan. In another example, fans 120 may be four wire fans that include a power and ground wire, tachometer signal wire, and a pulse width modulation (PWM) signal drive wire to allow controller 130 to control the speed of the fans. In another example, fans 120 may be four wire fans that include a power and ground wire along with a two wire data communication bus. Controller 130 controls these fans by providing data inputs to the fans using the communication bus and may monitor the operation of the fan by, for instance, requesting and/or receiving operating status or error messages from the fans over the communication bus.

The information processing elements 140 may include any information processing and/or networking components, such as processors, memory devices, network interface devices, and the like, that are configured to operate as information processing and/or networking devices in the information processing system. Examples of information processing and/or networking devices include, but are not limited to, servers, network switches, network routers, and storage nodes or arrays.

The controller 130 includes fan control logic 132 and power supply power sharing logic control 135. The fan control logic 132 is configured to control the operation of the fans 120, in a manner similar to that described above, in order to provide cooling to the power supplies 110 along with the controller 130 and the information processing elements 140. The power supply power sharing logic control 135 is configured to control the operations of the power supplies 110, including controlling the power sharing ratio as described above, based on the state of operation for information processing system 100. Power supply power sharing logic control 135 includes fan failure detection logic 136 configured to detect a failure of one of the fans 120. In some implementations, the fan failure detecting logic may detect a failure by determining if current is flowing to the fans 120 when powered on and/or by determining if a rotational speed for the fans 120 is not equal to a rotational speed set by fan control logic 132.

The power supply power sharing logic control 135 also includes power supply power sharing adjustment logic 137 configured to adjust the power sharing ratio for each of power supplies 110 from a default ratio as part of normal operation to an adjusted ratio in response to detecting the failure of the one of the fans 120. In some implementations, the power supply power sharing adjustment logic may be configured to identify the power supply out of the power supplies 110 which is associated with, or otherwise primarily cooled by, the one of the fans 120 that has failed. The power supply power sharing adjustment logic may be further configured to adjust the power sharing ratio to adjust the electrical energy provided by the identified power supply to be less than the electrical energy supplied by each of the remainder of the power supplies.

For example, in an implementation in which M=4 fans 120 are provided and N=2 power supplies 110 are provided, and operating information processing system 100 using a default power sharing ratio of 50:50, fan failure detection logic 136 detects a failure of fan 120a using a monitoring technique described above. As a result, power supply power sharing adjustment logic 137 adjusts the power sharing ratio such that power supply 110a, which is affected by the failure of fan 120a, provides 33% of the electrical energy and power supply 110b provides the remaining 67% of the electrical energy, resulting in an adjusted power sharing ratio of 33:67. In other words, the default power sharing ratio comprises an equal share for each of the power supplies, and the adjusted power sharing ratio corresponds to the proportional distribution of the fans that are not failed amongst the power supplies. Other implementations, such as those containing more fans 120 and/or more power supplies 110, different power sharing ratios may be used.

For example, the controller 130 may be configured to access a list of entries (e.g., in the form of a table) that provides an adjusted ratio for each combination of failures for fans 120 for one or more arrangements of power supplies 110 and fans 120. The list may be generated and/or programmed into the controller at the time of assembly of the information system.

For example, if two or more fans 120 provide cooling to each of the power supplies 110, the default ratio may remain 50:50. The adjusted ratio may be determined, in some examples, as:

$$Adjusted Power Sharing Ratio = ( A / C ) : ( B / C ) \qquad ( eq . 1 )$$

where:
A is the number of non-failed fans cooling the power supply associated with the failed fan;
B is the number of non-failed fans cooling the other power supply of the two power supplies;
C is the total number of non-failed fans;
(A and B may include fractional portions of fans).

Controller 130 adjusts the power sharing ratio by changing the load balance point between the power supplies 110. The load balance point is the operating point established, based on characteristics, for each of the power supplies 110 to assure that each power supply 110 provides the correct amount of electrical energy without one or more of the power supplies 110 attempting to provide electrical energy back into one of the other power supplies 110. The load balance point may be changed by introducing an offset to one of the characteristics of the power supplies 110.

For example, the load balance point may be changed by applying an offset signal to the droop curve characteristic of one or more of the supplies 110. The droop curve characteristic, also referred to as a load line, reflects the tendency of a power supply 110 to output a lower voltage as the load current provided to the load 190 (e.g., fans 120, controller 130, and information processing elements 140) increases. The droop curve characteristics of each of the power supplies 110 are used to maintain the load balance by applying feedback, usually in the form of a resistance, to compensate for the different droop curve characteristics of the power supplies 110 during a normal operating state. An offset signal, as either a voltage or a current, may be applied into the feedback to change the value of resistance used to maintain the load balance, effectively changing the load balance point between the power supplies 110.

In some examples using an active shift load balance mechanism for power supplies 110, the load balance point may be changed by applying an offset current to the operational amplifier that is used to maintain even power sharing between power supplies 110. The additional offset current can be used to shift the power sharing ratio proportionally to the amount of offset current.

In some, examples, the power supplies 110 may include a data communication circuit to allow the operation of the power supplies to be programmed and monitored by controller 130. These power supplies 110, referred to as smart power supplies may include sensors and adjustment mechanisms to adjust and control the amount of electrical energy (e.g., one or both of current and voltage) that can be supplied as part of a redundant power supply system. Controller 130 may adjust the power sharing ratio by providing a communication signal to each of the power supplies 110 to adjust the amount of electrical energy that is supplied.

Controller 130 may be implemented using any combination of hardware and/or software. For example, controller 130 may be implemented using a dedicated processing device, such as a microprocessor, configured to implement the operations included in fan control logic 132 and power supply power sharing logic control 135. Although controller 130 is shown separate from the power supplies 110, fans 120, and information processing elements 140, in some implementations, controller may be incorporated into one of those elements. For example, controller 130 may be incorporated as part of one of the information processing elements 140. In another example, the controller 130 may be incorporated as part of one of the power supplies 110. In another example, the controller 130 may be incorporated as part of one of the fans 120. In other examples (not illustrated), the controller 130 may be part of a separate device, such as a chassis or system controller which controls aspects of multiple servers installed therein, or a network controller which controls multiple networking devices, etc.

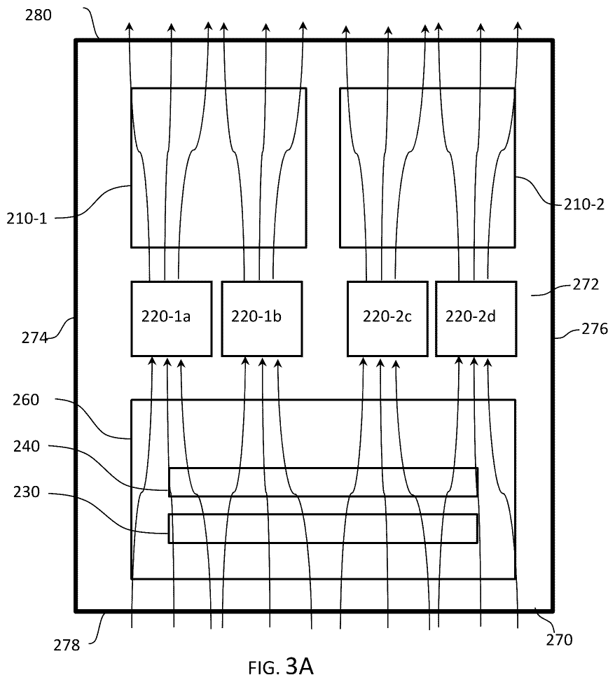

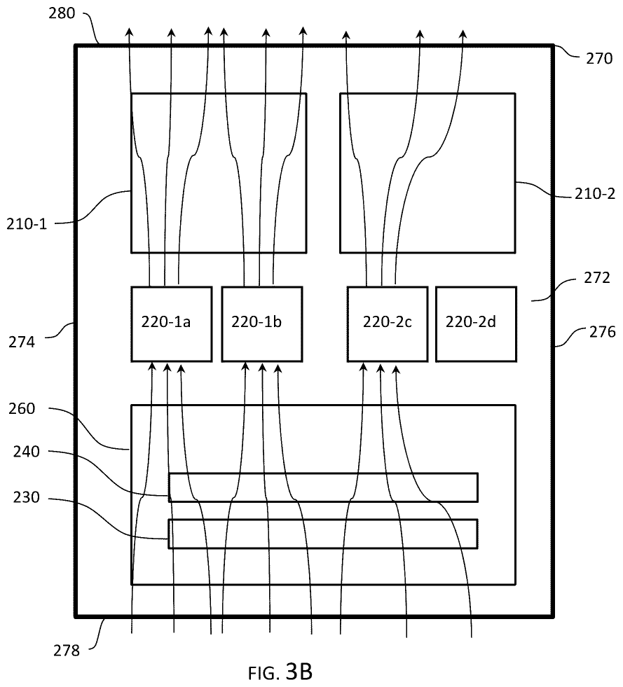

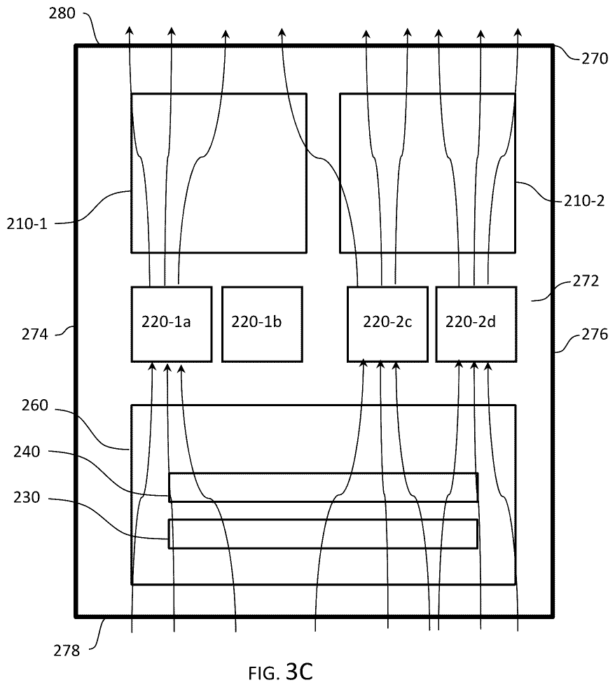

Various information process systems which are example configurations or implementations of the system 110 will be described below with reference to FIGS. 3A-9C. In these figures, airflow paths or patterns through the various example information processing systems are illustrated by arrows. These illustrations are schematic in nature and show conceptually the general directions of block airflow, but they are not intended to depict the precise paths that air will follow.

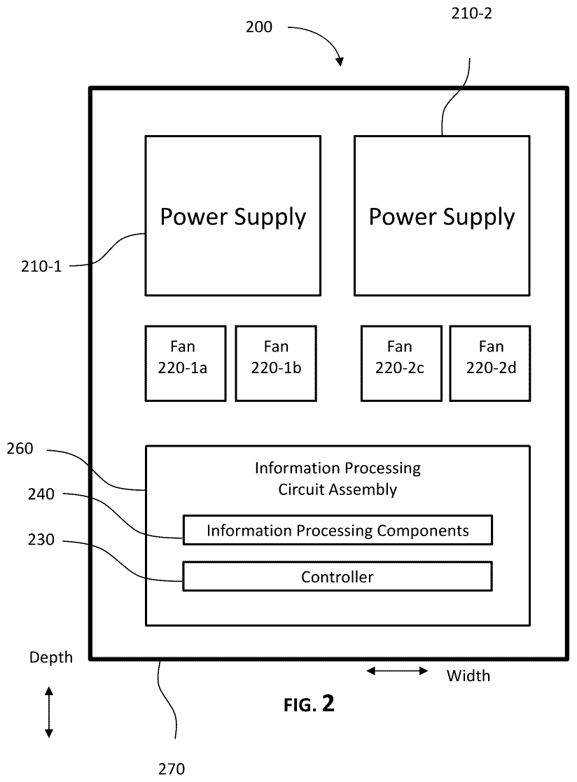

Turning now to FIGS. 2-5, a block diagram conceptually illustrating an information processing system 200 comprising a system chassis 270 in accordance with various aspects of the disclosure is described. The system chassis 270 further comprises power supplies 210-1 and 210-2 (collectively referred to as power supplies 210), fans 220-1a, 220-1b, 220-2c, and 220-2d (collectively referred to as fans 220) and information processing circuit assembly 260. It should be understood that FIGS. 2-5 are not intended to illustrate specific shapes, dimensions, or other structural details accurately or to scale, and that implementations the information processing system 200 and system chassis 200 may have different numbers and arrangements of the illustrated components and may also include other parts that are not illustrated.

The information processing system 200 may represent one configuration of the information processing system 100 described above. Thus, various components of the information processing system 200 may be similar to components of the information processing system 100 described above. The above descriptions of components of the information processing system 100 are applicable to the similar components of the information processing system 200, and thus duplicative descriptions are omitted below to improve clarity. Similar components of the information processing system 100 and 200 are given reference numbers having the same last two primary digits, such as 110 and 210. Although the information processing system 200 may be one configuration of the information processing system 100, the information processing system 100 is not limited to the configuration of information processing system 200.

Various elements of the information processing system 200 are illustrated in various arrangements in multiple figures. Further, various elements of the information processing system 200 are illustrated in multiple figures in various operational states. In addition, it should be understood that when certain figures are referred to in relation to a particular element, other figures besides those that are identified may also illustrate the same part from other arrangements or operational states.

FIG. 2 shows information processing system 200 without any electrical power applied, otherwise referred to as a non-operational state. Information processing system 200 comprises two power supplies 210-1 and 210-2. The system chassis 270 can be in the general shape of a hollow cube or a hollow rectangular cuboid having a base, 272, two lateral sides 274 and 276, a front side 278, a back side 280, and a top (not shown). One or more of the base 272, lateral sides 274 and 276, front side 278, back side 279, and top may be omitted or may be discontinuous and/or may have openings formed therein. The system chassis 270 has a height, width and depth that can accommodate the power supplies 210, fans 220, and information processing circuit assembly 260. Width and depth dimensions are indicated in FIG. 2, with the height dimension being perpendicular to the width and height dimensions (i.e., extending into the page in FIG. 2). The server chassis 270 can be formed out of a suitable structural material. Suitable structural materials include, but are not limited to, metals such as steel, copper, brass, aluminum, or other relatively rigid materials such as plastics. In one example, the server chassis 270 is formed out of steel having a thickness of 1.0 millimeter (mm) and has a height of 4.45 centimeters (cm), a width of 22.50 cm, and a depth of 53.30 cm.

The system chassis 270 is described herein in an orientation in which the base of system chassis 270 is generally horizontal, and directional terms such as “lateral,” “top”, “bottom” and so on are used herein relative to this illustrated orientation. For example, the base is described herein as being coupled to the lateral sides of the system chassis 270. This may be referred to herein as a horizontal configuration. However, it should be understood that the system chassis 270 could be oriented differently, for example with the “base” extending vertically. This may be achieved, for example, by rotating the entire system chassis 270 by 90 degrees. The principles of the present disclosure may equally apply regardless of the orientation of the system chassis 270, with the “base” oriented in a vertical direction, referred to as a vertical configuration. In such implementations in which the system chassis 270 has different orientations than those illustrated, it should be understood that the directional terms used herein would be translated accordingly, e.g., that which is described as located on a “lateral side” of the system chassis 270 in relation to the horizontal configuration shown in FIG. 1 may be located on a “top” or “bottom” side of the system chassis 270 in a vertical configuration.

The power supplies 210, fans 220, and information processing circuit assembly 260 are attached to the inner surface of the base 272 of system chassis 270 using any well-known fastening mechanism (not shown), such as screws, rivets, push pin retainers, and the like.

The information processing circuit assembly 260 comprises electronic circuits such as processors, memory, networking circuits, and printed circuit boards, that form information processing components 240 that are similar to the information processing elements 140 described in FIG. 1. Information processing circuit assembly also comprises controller 230, similar to controller 130. In other examples, the controller may be included with one of the power supplies 210, one of the fans 220, or may be a separate circuit assembly and attached to the system chassis 270 in a manner similar to that described above.

One or more of the base 272, lateral sides 274 and 276, front side 278, back side 280, and top of system chassis 270 may have perforated sections for ventilation. The perforated sections allow air flow in and out of the interior of system chassis 270 and, in conjunction with fans 220, provide cooling to the electrical elements, including power supplies 210. The perforated sections may include a plurality of openings of various sizes and/or shapes that pass air but prevent unintentional intrusion by other objects. These perforated sections may also help to prevent electromagnetic interference, in some examples. As described below, the front side 278 and back side 280 include perforations arranged along the width of system chassis 270. In other implementations different arrangements for the perforated sections may be used. In addition to air entering the system chassis 270 via perforated sections, air may also enter the system chassis 270 through other gaps or openings; for example, in some systems one or more panels of the system chassis 270 has an array of bays to receive pluggable modules (e.g., pluggable solid-state-drives), and air may enter the chassis 270 through gaps between and around these pluggable modules.

As noted above, the information processing system 200 comprises controller 230. The controller may be configured to detect fan failures and perform the power supply power sharing adjustment operations in response thereto, as described above in relation to controller 130. More specifically, if one of the fans 220 fails, then in response the controller 230 may adjust the power supply sharing ratio away from the default ratio to an adjusted ratio, wherein in the adjusted ration the power supply 210 that is associated with the failed fan has a lower proportional share of the overall amount of power. For example, if fan 220-1a fails, then the amount of power supplied by power supply 210-1 would be decreased because the failed fan 220-1a is associated with (i.e., provided cooling to) power supply 210-1. In some examples, all of the fans associated with a given power supply are treated the same for purposes of the power sharing ratio adjustment—for example, the same adjustment occurs whether fan 220-1a or fan 220-1b fails. In other examples, different adjustments may be made depending on which particular fan fails, even as between fans that are associated with the same power supply—for example, one adjustment may occur if fan 220-1a fails while a different adjustment may occur if fan 220-1b fails. Examples of the foregoing will be described in greater detail below with reference to FIGS. 3A-3C.

FIG. 3A shows information processing system 200 in a normal operating state. In the normal operation state, all elements are operating properly, with power supplies 210 operating in a default power sharing ratio and all of the fans 220 providing cooling to the power supplies 210 and information processing circuit assembly. Power supplies 220 provide electrical power in parallel to the information processing circuit assembly 260 and fans 220 based on a default power sharing ratio (e.g., 50:50). The fans 220 provide cooling to the electrical and electronic components included on power supplies 210 as well as processing circuit assembly. In general, the cooling provided by fans 220 reduces the ambient air temperature around the electrical and electronic components, (which are producing heat as part of their operation) to reduce heat stress and maintain operational reliability. Air flow lines, shown with arrows, indicate a flow direction of air entering and exiting the fans 220 to provide an exemplary air flow pattern. Outside air enters system chassis 270 through a set of openings at the front side 278 and flows over the information processing circuit assembly 260 to the fans 220. The air flows out of the fans 220, over the power supplies 210 and exits system chassis 270 through a set of openings at the back side 280.

As shown in FIG. 3A, all four fans 220 provide cooling to the information processing circuit assembly 260 while fans 220-1a and 220-1b provide cooling primarily to power supply 210-1 and fans 220-2c and 220-2d provide cooling primarily to power supply 210-2. In this manner, each of the two power supplies 210 is cooled by, and associated with, two of the four fans 220.

FIG. 3B shows information processing system 200 operating in an abnormal operating state. In the abnormal operating state of FIG. 3B, fan 220-2d has failed or otherwise stopped operating properly. The air flow lines indicate that no air flow is entering or exiting fan 220-2d. As a result, power supply 210-2 has less air flow over its components, and consequently less cooling, than power supply 210-1. Notably, the lack of air flow from fan 220-2d may alter the air flow pattern over power supply 220-2 produced by fan 220-2c as is shown in FIG. 3B. However, due to the location of fan 220-2d with respect to power supply 220-1, the air flow pattern over power supply 210-1 may be little changed or unchanged.

In order to account for the lower amount of air flow over power supply 220-2, an adjustment to the power sharing ratio between power supplies 210-1 and 210-2 is made. More specifically, the adjustment is made in response to a detection that the fan 220-2d has failed. In some examples, power supply 210-2 may be identified as associated with power supply 220-2d and the power sharing ratio may be adjusted from a default ratio of 50:50 to a ratio of 67:33. Notably, a similar adjustment may be made if fan 220-1a has failed instead of fan 220-2c.

FIG. 3C shows information processing system 200 operating in another abnormal operating state. In the abnormal operating state in FIG. 3C, fan 220-1b has failed or otherwise stopped operating properly. Air flow lines are shown in FIG. 3C indicating that no air flow is entering or exiting fan 220-1b. As a result, power supply 210-1 has less air flow over its components than power supply 210-1.

In order to account for the lower amount of air flow over power supply 220-1, an adjustment to the power sharing ratio between power supplies 220-1 and 220-2 is made. More specifically, the adjustment is made in response to a detection that the fan 220-2b has failed. In some examples, power supply 210-1 may be identified as associated with power supply 220-1b and the power sharing ratio may be adjusted from a default ratio of 50:50 to a ratio in which the power supply 210-1 supplies a smaller proportional share. For example, in some cases the adjusted ratio may be a ratio of 33:67 in a manner as described above.

In some examples, aside from determining which power supply 210 is associated with the failed fan 220, which particular fan 220 has failed or its location does not affect what the adjusted power sharing ratio is. In some of these examples, the adjusted power sharing ratio is a ratio of 33:67, and this same ratio would be used regardless of whether the fan 220-1b or 220-1a failed (the same ratio would also be used if the fan 220-2c or 220-2d were to fail, but in that case it would be the power supply 210-2 which provides the smaller share, in a manner as described above in relation to FIG. 3B).

In some other examples, a different power sharing ratio may be used based on which fan 220 has failed. Specifically, in some examples, when a fan that is located distant from the opposing power supply fails, the adjustments to the power sharing ratio may be greater than when a fan that is located adjacent to the opposing power supply fails. In the case of FIG. 3C, this means that the adjustment is greater when one of the fans 220-1a or 220-2d fails as compared to when one of the fans 220-1b or 220-2c fails. The reason for this disparate treatment based on fan location is that different amounts of air may be supplied to the respective power supplies depending on the location of the failed fan 220. In particular, when the failed fan is adjacent to the opposing fan, a low pressure region behind the failed fan 220 may draw in some of the air which would have been allocated to the other power supply under normal conditions, whereas when the failed fan is distinct from the opposing power supply, less air (if any) will be drawn over from the flows allocated to the other power supply. For example, as shown in FIG. 3C, some of the air from fan 220-2c, which previously would have flowed over power supply 210-2, may instead be drawn over to flow over power supply 210-1 due to the failure of the fan 220-1b. Accordingly, to account for the difference in airflow received by the power supplies depending on the location of the failed fan, a different adjusted ratio is used depending on fan location. The amount of airflow that is drawn off in this manner is small, and thus power supply 210-1 the power supply associated with the failed fan is still allocated a lower proportional share, but the amount by which its share is decreased may be less than in other cases in order to account for the change in air flow over power supply 220-2. For example, the adjusted ratio may be 40:60 instead of 33:67. Notably, a similar adjustment may be made if fan 220-2c has failed instead of fan 220-1b.

FIGS. 3A-3C shows information processing system 200 with the power supplies 210, fans 220, and information processing circuit assembly 260 in a particular arrangement, namely with fans 220 positioned between power supplies 210 (closest to the back side) and the information processing circuit assembly 260 (closest to the front side) on system chassis 270. Other arrangements and orientations may be used.

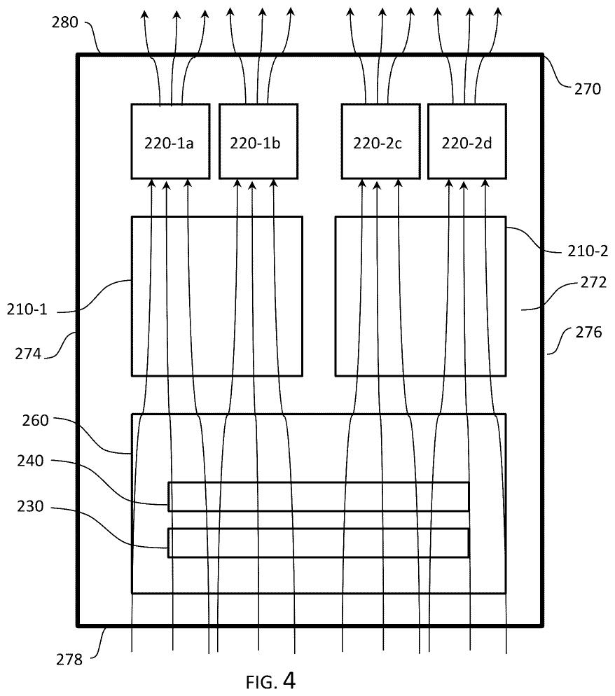

For example, FIG. 4 shows information processing system 200 in another arrangement and operating in a normal operating state. In FIG. 4, the power supplies 210 are positioned between the fans 220 (positioned closest to the back side) and the information processing circuit assembly 260 (closest to the front side) on system chassis 270. In this arrangement, outside air enters system chassis 270 at the front side 278 and flows over the information processing circuit assembly 260 and over the power supplies 210 to the fans 220. The air flows out of the fans 220 and exits at the back side 280 of system chassis 270. The air flow direction may be reversed based on the operation of the fans 220, as described above. In the examples of FIG. 4, the same power sharing ratio adjustment procedures as were described above in relation to FIGS. 2-3C may be performed.

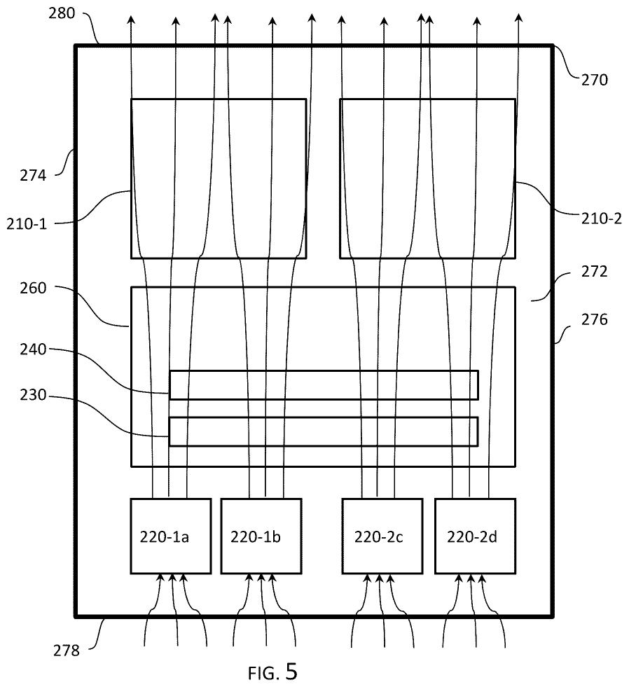

For example, FIG. 5 shows information processing system 200 in another arrangement and operating in a normal operating state. In FIG. 5, the information processing circuit assembly 260 is positioned between the power supplies (closest to the back side) and the fans 220 (positioned closest to the front side) on system chassis 270. In this arrangement, outside air enters system chassis 270 at the front side 278 and flows to the fans to 220. The air flows out of the fans 220, over the information processing circuit assembly 260, over the power supplies 210, and exits at the back side 280 of system chassis 270. The air flow direction may be reversed based on the operation of the fans 220, as described above. In the examples of FIG. 4, the same power sharing ratio adjustment procedures as were described above in relation to FIGS. 2-3C may be performed.

Notably, the air flow patterns shown in FIGS. 3-5 indicates air flow from the front side 278 towards the back side 280 of system chassis 270. In other examples, the air flow pattern can indicate air flow from the back side 380 to the front side of system chassis 270. This air flow pattern can be generated by, for instance, reversing the direction of airflow through fans 220.

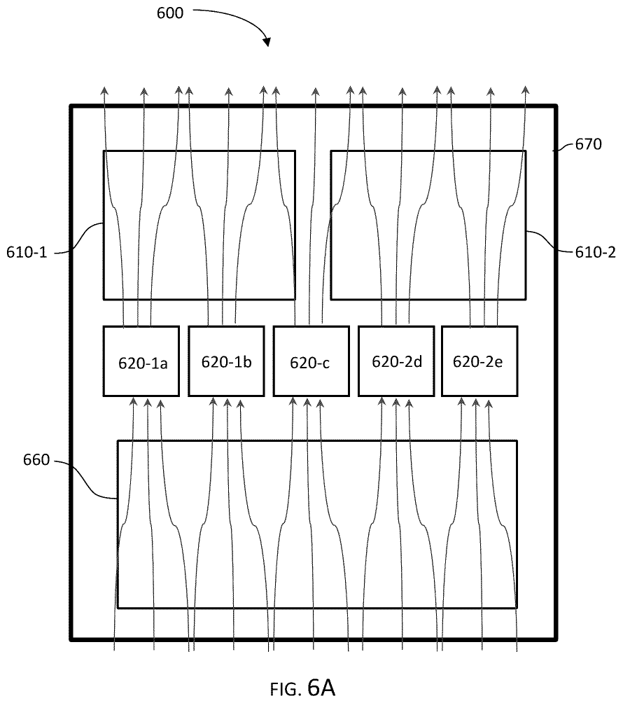

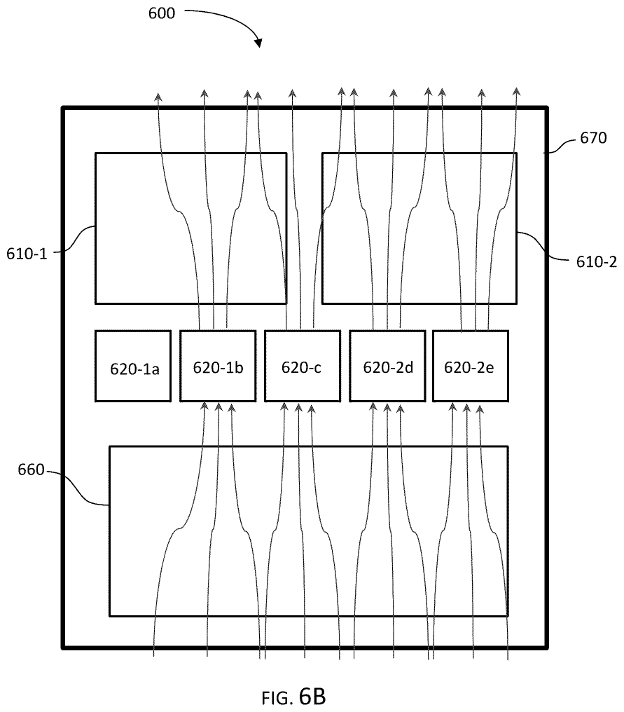

Turning now to FIGS. 6-9, block diagrams conceptually illustrating an information processing system in various additional configurations in accordance with various aspects of the disclosure are described. Various components of the information processing systems in FIGS. 6-9 may be similar to components of the information processing system 200 described above. The above descriptions of components of the information processing system 200 are applicable to the similar components of the information processing systems described in FIGS. 6-9, and thus duplicative descriptions are omitted below to improve clarity. Further, components used in FIGS. 6-9 are given similar reference numbers in a manner similar to that described in FIG. 2.

FIG. 6A shows an information processing system 600 operating in a normal operating state. In FIG. 6A, five fans 620 provide cooling to the information processing circuit assembly 660 while fans 620-1a and 620-1b provide cooling primarily to power supply 610-1 and fans 620-2d and 620-2e provide cooling primarily to power supply 610-2. Fan 620-c provides cooling to both power supply 610-1 and power supply 610-2, the arrangement and orientation, as shown, allowing a substantially equal amount of cooling to both. In this manner, each of the two power supplies 610 is cooled by two of the five fans 620 while the remaining fan provides cooling to both power supplies 610.

FIG. 6B shows information processing system 600 operating in an abnormal operating state. In the abnormal operating state of FIG. 6B, fan 620-1a has failed or otherwise stopped operating properly. The air flow lines indicate that no air flow is entering or exiting fan 620-1a. As a result, power supply 610-1 has less air flow over its components, and consequently less cooling, than power supply 610-2. In response to detecting the failure of the fan 620-1a, in order to account for the lower amount of air flow over power supply 610-1, an adjustment to the power sharing ratio between power supplies 610-1 and 610-2 is made. The adjusted power sharing ratio may be determined using one of the techniques described above. For example, in some examples, power sharing ratio may be determined, using the formula in equation 1 described above, to be 37.5:62.5.

Notably, a similar adjustment to the power sharing ratio may be made if the controller detects that fan 620-1b, fan 620-2d, or fan 620-2e has failed instead of fan 620-1a. Further, if the controller detects that fan 620-c has failed instead of fan 620-1a, no adjustment may be made based on cooling being shared substantially equally (i.e., the failed fan 620-c previously provided airflow equally to both power supplies 610-1 and 610-2, and therefore neither power supply 610 is receiving more cooling than the other after the failure of fan 620-c).

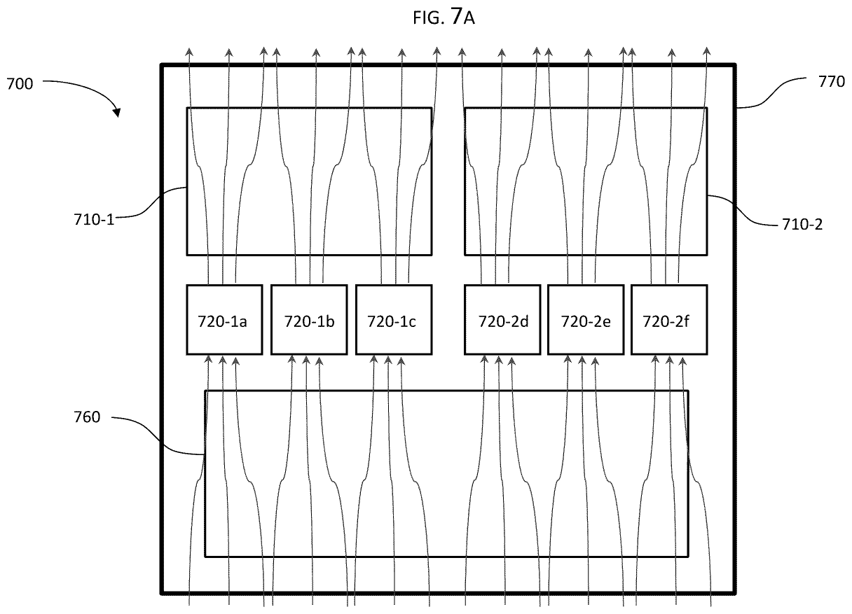

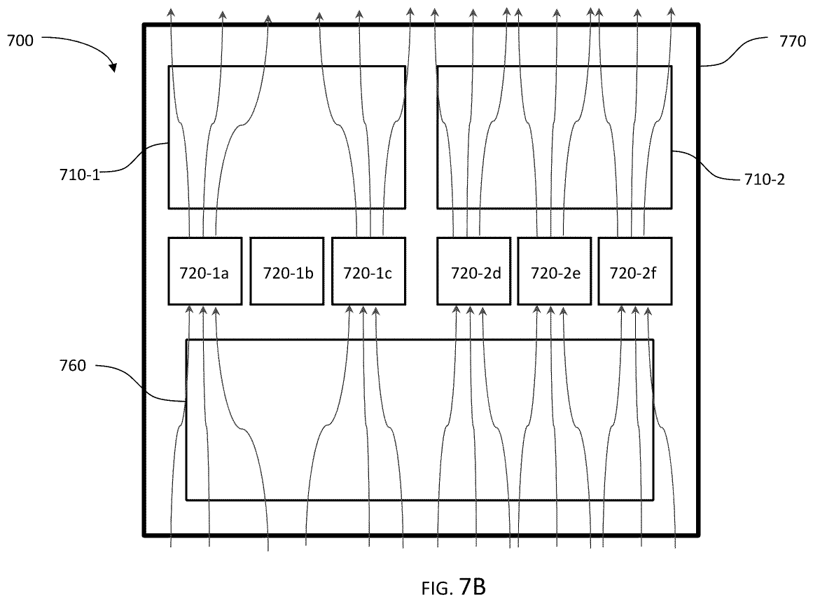

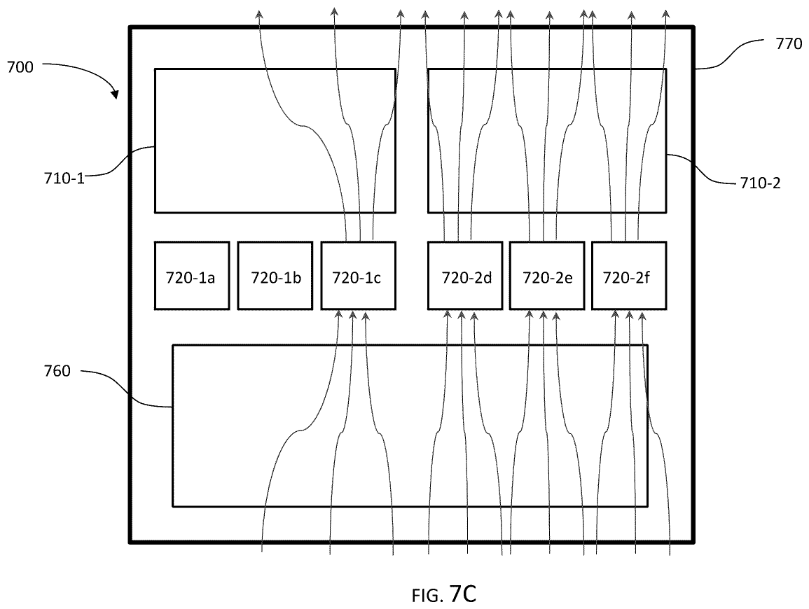

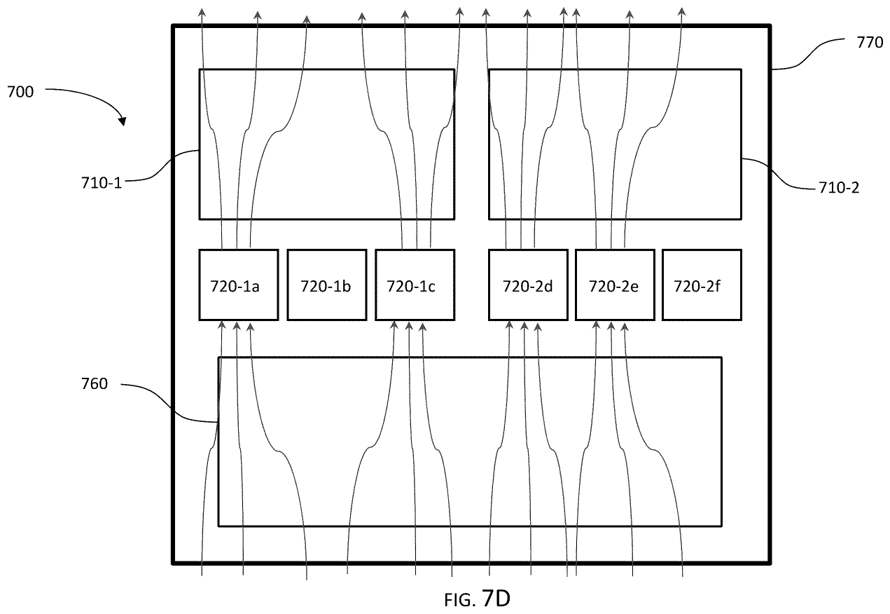

FIG. 7A shows information processing system 700 operating in a normal operational state. In FIG. 7A, all six fans 720 provide cooling to the information processing circuit assembly 760 while fans 720-1a, 720-1b, and 720-1c provide cooling primarily to power supply 710-1 and fans 720-2d, 720-2e, and 720-2f provide cooling primarily to power supply 710-2. In this manner, each of the two power supplies 710 is cooled by three of the six fans 720.

FIG. 7B shows information processing system 700 operating in an abnormal operating state. In the abnormal operating state of FIG. 7B, fan 720-1b has failed or otherwise stopped operating properly. The air flow lines indicate that no air flow is entering or exiting fan 720-1b. As a result, power supply 710-1 has less air flow over its components, and consequently less cooling, than power supply 710-2. In response, and in order to account for the lower amount of air flow over power supply 710-1, an adjustment to the power sharing ratio between power supplies 710-1 and 710-2 is made. The adjusted power sharing ratio may be determined using one of the techniques described above. For example, power sharing ratio may be determined, using the formula in equation 1 described above, to be 40:60.

Notably, a similar adjustment may be made if the controller detects that fan 720-1a, 720-1c, fan 720-2d, 720-2e, or fan 720-2f has failed instead of fan 720-1b.

In some examples, in some examples, the amount of adjustment may differ depending on the location of the failed fan, as was described above in relation to FIG. 3C. Thus, in some examples, if the controller detects that either fan 720-1c or fan 720-2d has failed instead of fan 720-1b, a different power sharing ratio may be used as compared to when any of the other fans 720 fail, in order to account for possibility of some airflow which was previously allocated to one power supply 710 being drawn off to the other power supply in a manner similar to that described in FIG. 3C.

FIG. 7C shows information processing system 700 operating in another abnormal operating state. In the abnormal operating state of FIG. 7C, both fan 720-1a and 720-1b have failed or otherwise stopped operating properly. While a failure of a second fan coincident with the failure of a first fan in an information processing system, while less likely, may still occur. The air flow lines indicate that no air flow is entering or exiting either fan 720-1a or 720-1b causing a further reduction in air flow, and consequently even less cooling, to power supply 710-1. In response to this additional fan failure, in order to account for the further reduction of air flow provided to power supply 710-1, a further adjustment to the power sharing ratio (from the first adjusted power sharing ratio that was implemented in response to the first fan failure to a second adjusted power sharing ratio) between power supplies 710-1 and 710-2 is made. The second adjusted power sharing ratio may be determined using one of the techniques described above. For example, the second adjusted power sharing ratio may be determined, using the formula described above, to be 25:75. Notably, a similar adjustment may be made if the controller detects that any two of fans 720-1a, 720-1b, 720-1c or 720-2d, 720-2e, and 720-2f have failed.

FIG. 7D shows information processing system 700 operating in another abnormal operating state. In the abnormal operating state of FIG. 7D, both fan 720-1b and fan 720-2f have failed or otherwise stopped operating properly. The air flow lines indicate that no air flow is entering or exiting either fan 720-1b or 720-2f. As a result, power supply 710-2 has less air flow over its components, and consequently less cooling, but the amount of air flow, and the amount of cooling, is now similar to power supply 710-1.

In order to account for the reduction of air flow provided to power supply 720-2 due to the failure of fan 720-2f, a further adjustment to the power sharing ratio (from 40:60 in FIG. 7B) between power supplies 720-1 and 720-2 is made. The adjusted power sharing ratio may be determined using one of the techniques described above. For example, power sharing ratio may be determined, using the formula described above, to be 50:50. Notably, a similar adjustment may be made if the controller detects that any one of fans 720-1a, 720-1b, 720-1c and any one of 720-2d, 720-2e, and 720-2f have failed.

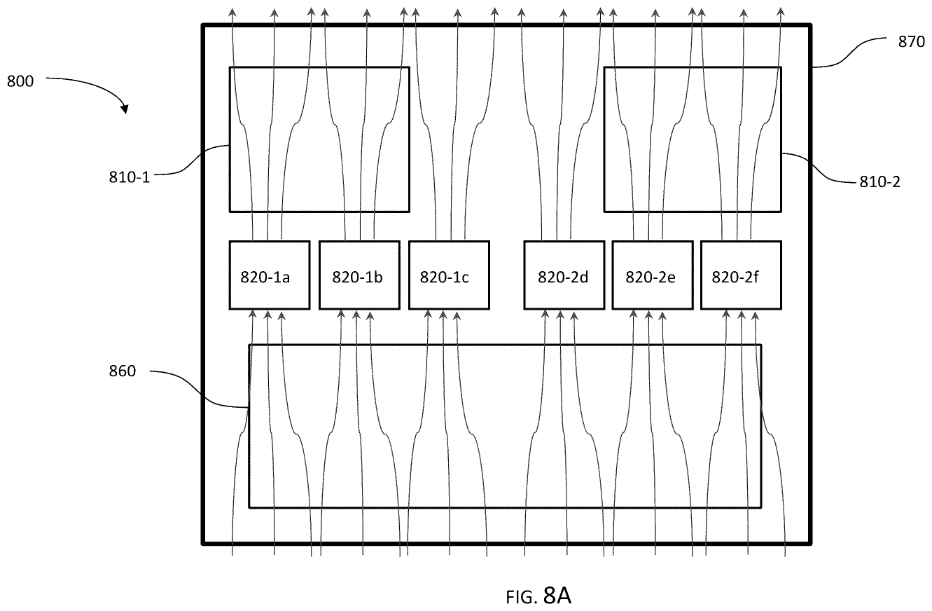

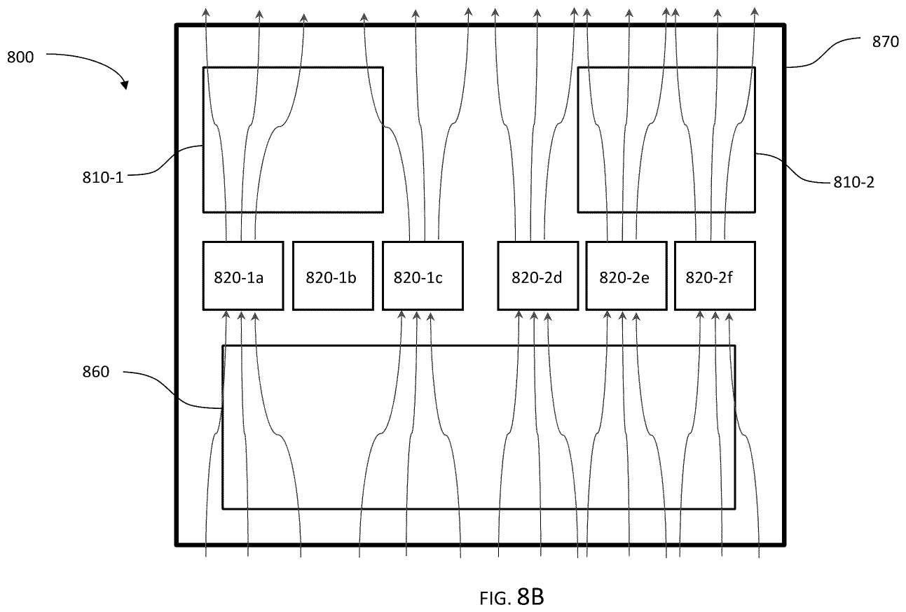

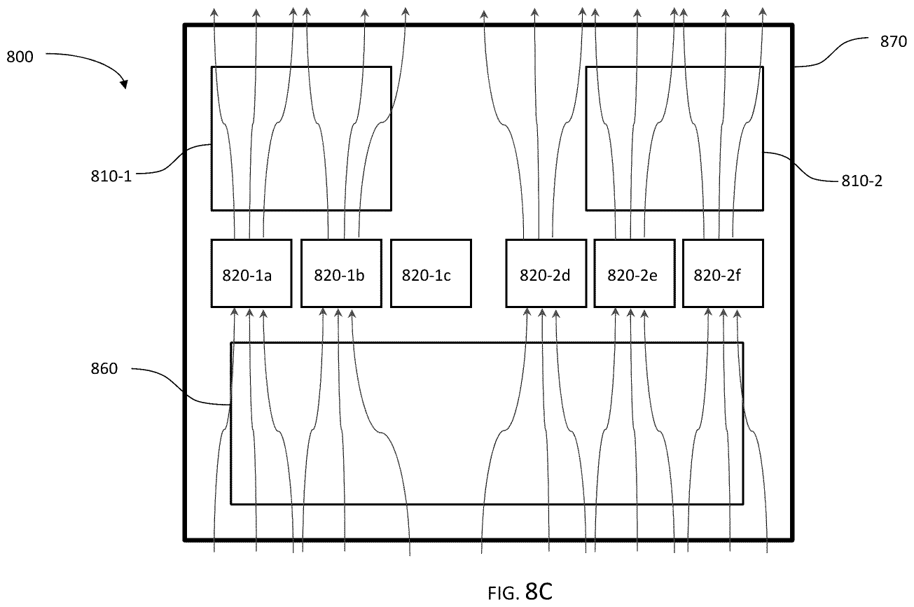

FIG. 8A shows information processing system 800 operating in a normal operational state. In FIG. 8A, all six fans 820 provide cooling to the information processing circuit assembly 860 while fans 820-1a, 820-1b provide cooling primarily to power supply 810-1 and fans 820-2e, and 820-2f provide cooling primarily to power supply 810-2. Fan 820-1c is associated with power supply 810-1 based on proximity to power supply 810-1 but little or no air flow passes over its components. Similarly, fan 820-2d is associated with power supply 810-2 for the same reason. In this manner, each of the two power supplies 810 is associated with three fans but cooled primarily by only two of the six fans 820.

FIG. 8B shows information processing system 800 operating in an abnormal operating state. In the abnormal operating state of FIG. 8B, fan 820-1b has failed or otherwise stopped operating properly. The air flow lines indicate that no air flow is entering or exiting fan 820-1b. As a result, power supply 820-1 has less air flow over its components, and consequently less cooling, than power supply 820-2. Further, as shown by the air flow pattern, a portion of the air flow from fan 820-1c (which normally may not provide cooling to power supply 810-1) may flow over power supply 810-1, providing some cooling.

In response to detecting the fan failure, and in order to account for the lower amount of air flow over power supply 810-1, an adjustment to the power sharing ratio between power supplies 810-1 and 810-2 is made. The adjusted power sharing ratio may be determined using one of the techniques described above. For example, the power sharing ratio may be determined, using the formula described above, to be 33:67. In some examples, a different power sharing ratio may be used in order to account for the additional air flow that is provided over power supply 810-1 by fan 820-1c (e.g., 40:60 instead of 33:67). Notably, a similar adjustment may be made if fan 820-2e has failed instead of fan 820-1b.

FIG. 8C shows information processing system 800 operating in another abnormal operating state. In the abnormal operating state of FIG. 8C, fan 820-1c has failed or otherwise stopped operating properly. The air flow lines indicate that no air flow is entering or exiting fan 820-1c. Fan 820-1c either does not provide cooling to either of power supplies 810 in a normal operating state, or supplies a smaller amount of cooling to one of the power supplies 810 than the other fans associated with that power supply 810. As a result, the adjustment (if any) that is made in response to the failure of the fan 820-1c may be different than it would be if the fan 820-1a or 820-1b were to fail. In some examples, the adjustment (if any) that is made may vary based on how much airflow the failed fan normally provides to the power supply; for example, if the failed fan provides some air to the power supply, but not the full amount that the other fans 820 provide, then the adjustment to the ratio may be smaller than if the other fan 820 were to fail, such as 45:55 instead of 40:60). If the failed fan provides very little or no airflow to either power supply 810, then no adjustment to the power sharing ratio between power supplies 810-1 and 810-2 may be made and the default power sharing ratio (e.g., 50:50) is used. However, as shown by the air flow diagram, some air flow from fan 820-1b is directed away from power supply 810-1, resulting in less cooling for power supply 810-1 than power supply 810-2. In some examples, a different power sharing ratio may be used in order to account for the change in the air flow pattern (e.g., 45:55 instead of 50:50). Notably, a similar adjustment may be made if fan 820-2d has failed instead of fan 820-1c.

The presence of fans, such as fans 820-1c and 820-2d in information processing system 800, that may not provide cooling to the power supplies in a normal operating state but may provide or remove cooling to one of the power supplies in an abnormal operating state may require a different formula than described above or may require the use of a set of specific power sharing ratios that depend on which fan has failed.

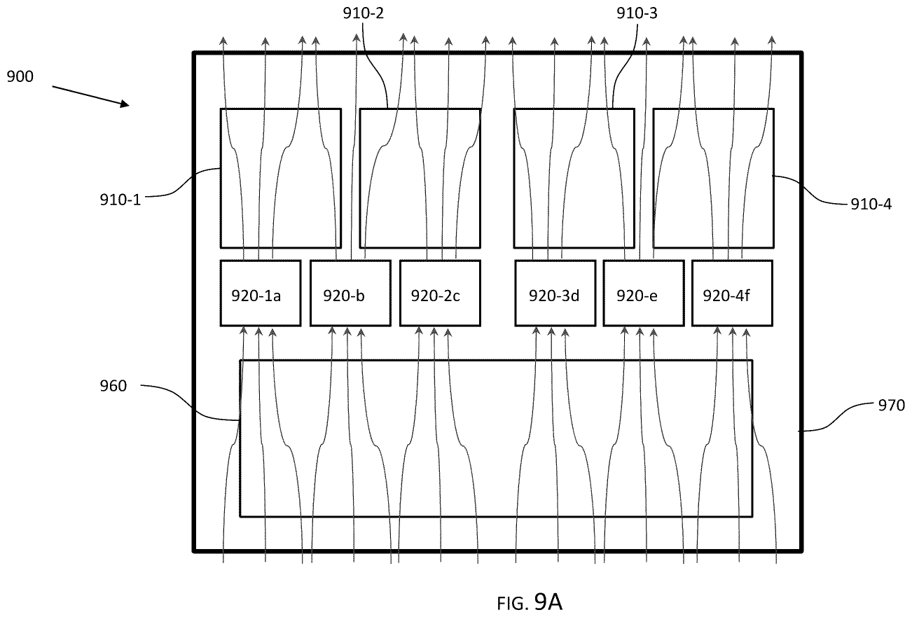

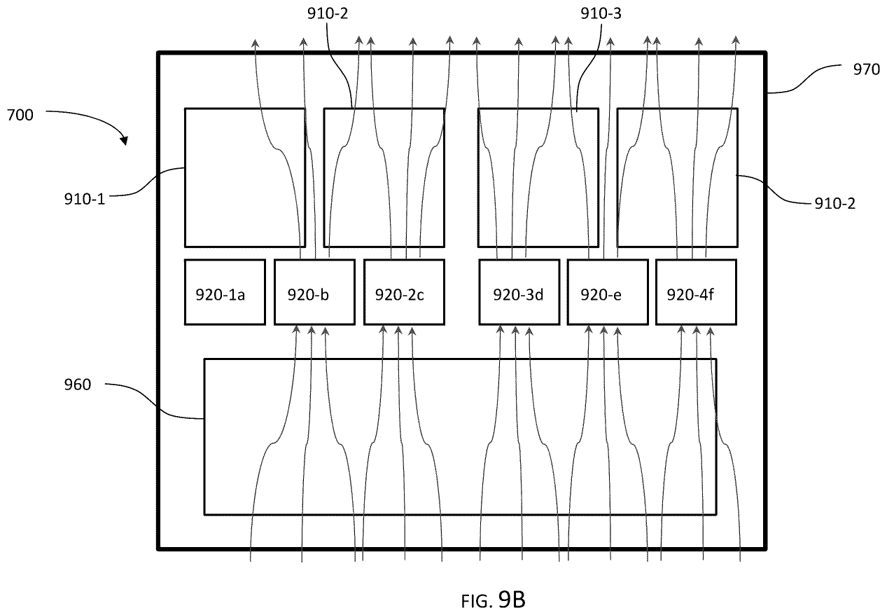

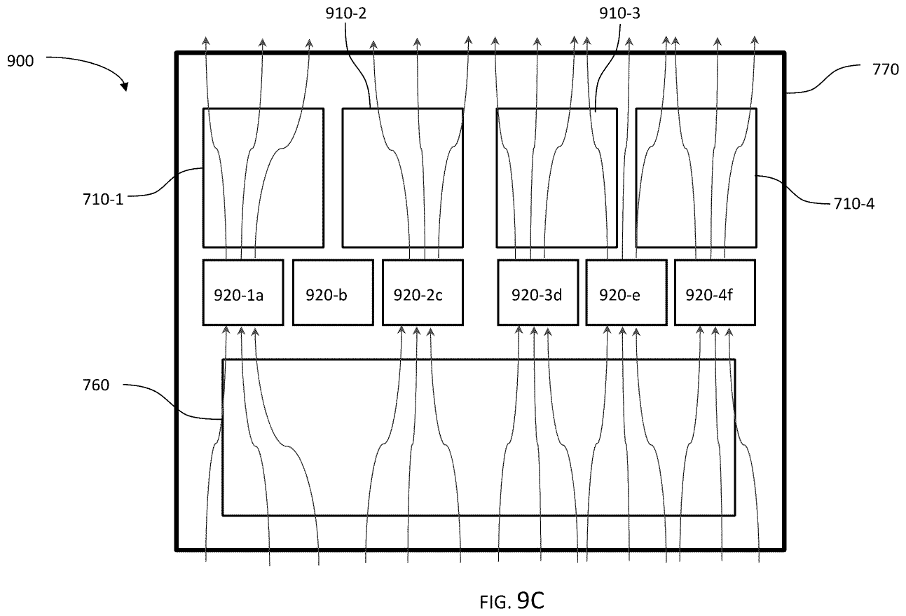

FIG. 9A shows information processing system 900 operating in a normal operational state. In FIG. 9A, all six fans 920 provide cooling to the information processing circuit assembly 960 while fan 920-1a provides cooling primarily to power supply 910-1, fan 920-2c, provides cooling primarily to power supply 910-2, 920-3d provides cooling primarily to power supply 910-3, and fan 920-4f provide cooling primarily to power supply 910-4. Fan 920-b provides cooling to both power supply 910-1 and power supply 910-2 while fan 920-d provides cooling to both power supply 910-3 and 910-4 similar to that described in FIGS. 6A-6. In this manner, each of the four power supplies 910 is cooled by one of the six fans 920 while one of the remaining fans 920 provides cooling to two of the power supplies 910 and the other one of the remaining fans 920 provides cooling to the remaining two of the power supplies 910. In other words, each power supply is cooled by two fans 920, but receives the full airflow from only one of these fans 920 and only part of the airflow from the other fan 920. Accordingly, some of the fans 920 may be “associated” with multiple power supplies 910.

The four power supplies 910 shown in FIG. 9A operate using a power sharing ratio containing four values rather than two values as described above. For example, the power sharing ratio for power supplies 910 may have a default ratio of 25:25:25:25, indicating that each of the power supplies 910 provide 25 percent of the total electrical energy that is provided to the remainder of information system 900.

FIG. 9B shows information processing system 900 operating in an abnormal operating state. In the abnormal operating state of FIG. 9B, fan 920-1a has failed or otherwise stopped operating properly. The air flow lines indicate that no air flow is entering or exiting fan 920-1b. As a result, power supply 910-1 has less air flow over its components, and consequently less cooling, than power supplies 910-2, 910-3, and 910-4. Further, as shown by the air flow pattern, a greater amount of the air flow from fan 920-b may flow over power supply 910-1 than power supply 910-2, providing less cooling to power supply 910-2 than power supplies 910-3 and 910-4.

In order to account for the lower amount of air flow over power supply 910-1, an adjustment to the power sharing ratio between power supplies 910-1, 910-2, 910-3, 910-4 is made. The adjusted power sharing ratio may be determined using one of the techniques described above. For example, the power sharing ratio may be determined, using a formula similar to that described above, to be 10:30:30:30. In some examples, a different power sharing ratio may be used in order to account for the change in air flow that has also occurred over power supply 920-2 (e.g., 15:25:30:30 instead of 10:30:30:30). Notably, a similar adjustment may be made if any of fans 920-2c, 920-3d, or 920-4f has failed instead of fan 920-1a.

FIG. 9C shows information processing system 900 operating in another abnormal operating state. In the abnormal operating state of FIG. 9C, fan 920-b has failed or otherwise stopped operating properly. The air flow lines indicate that no air flow is entering or exiting fan 920-b. As a result, both power supplies 920-1 and 920-2 have less air flow over its components, and consequently less cooling, than power supplies 920-3 and 920-4.

In response to the fan failure, in order to account for the lower amount of air flow over power supplies 910-1 and 910-2, an adjustment to the power sharing ratio between power supplies 910-1, 910-2, 910-3, 910-4 is made. The adjusted power sharing ratio may be determined using one of the techniques described above. In contrast to the situation in FIG. 9B, in this case the failed fan 920-b is associated with two power supplies 910-1 and 910-2, and therefore in the adjusted ratio the proportional share of both of these power supplies 910-1 and 910-2 are reduced relative to the other power supplies 910-3 and 910-4. Moreover, another difference from the scenario in FIG. 9B is that in FIG. 9C the failed fan 920-b does not supply its full airflow to either power supply 910-1 or 910-2, but instead supplies some smaller amount. Therefore, although these power supplies 910-1 and 910-2 are receiving less cooing due to the failure of the fan 920-b, the reduction in cooling experienced by each is less than the reduction in cooling that was experienced by the power supply 910-1 when the fan 920-1a failed. Accordingly, the proportional share for both power supplies 910-1 and 910-2 are adjusted, but to a lesser degree than when the fan 920-1a failed. For example, the power sharing ratio may be determined, using a formula similar to that described above, to be 20:20:30:30. Notably, a similar adjustment may be made if fan 920-e fails instead of fan 920-c.

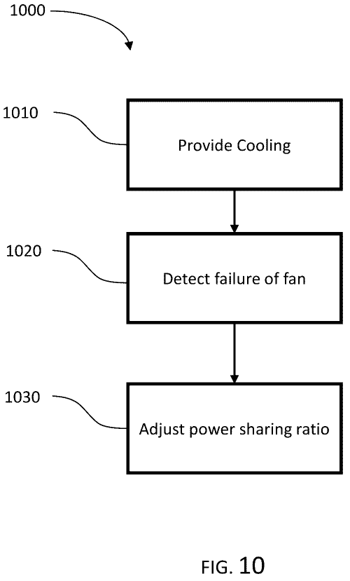

FIG. 10 is a process flow diagram illustrating an example process 1000 for power supply power sharing adjustment in an information processing system. In block 1010, cooling is provided to elements of the information processing system, including a set of power supplies 110 used to provide electrical energy to electrical components used for the information processing system. The power supplies 110 operate as redundant power supplies with power sharing. The power sharing ratio between the power supplies 110 is set to a default ratio (e.g., 50:50) during a normal operating state. The cooling is provided by a set of fans. For example, the set of fans may provide cooling to each of the power supplies by generating a flow of air over the electrical and electronic components included in each of the power supplies.

In block 1020, a failure of a fan that is used for cooling the elements of the information processing system is detected. The detection may be performed by controller 130. For example, controller 130 may detect the failure by determining whether a rotational speed for the fan is substantially different than the programmed rotational speed for the fan, such as when the rotational speed is less than a programmed rotational speed by more than 10 percent or some other threshold value. For example, controller 130 may detect the failure by determining whether one of the fans returns an error signal or alternatively does not return an expected. For example, controller 130 may detect the failure by determining whether one of the fans is not drawing current when a voltage is applied.

In block 1030, the power sharing ratio for the set of power supplies is adjusted in response to detecting the failure of the one fan in block 120. The power sharing ratio is adjusted by controller 130, which adjusts the power sharing ratio from the default ratio in block 110 to an adjusted ratio. For example, the adjusted ratio may correspond to the proportional distribution of the fans that are not failed amongst the power supplies. The adjusted ratio may be determined using a list of specific ratios corresponding to failures of specific fans or may be adjusted using one or more formulas. In a specific example using two power supplies 110, with each of the power supplies 110 being cooled by two fans, the default ratio may be 50:50 and the adjusted ratio may be 33:67.

The controller 130 may adjust the power sharing ratio of the power supplies by applying an offset to a characteristic of one or more of the power supplies 110. For example, controller 130 may apply an offset signal to the droop curve characteristic of one or more of the supplies 110. In another example, controller 130 may apply an offset current to the circuit that is used to maintain even power sharing between power supplies 110. In another example, controller 130 may reprogram one or more of the power supplies 110 to change the amount of electrical energy that can be provided as part of the redundant power supply system.

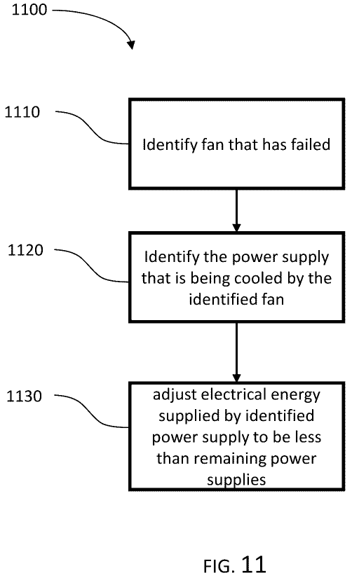

FIG. 11 describes an example process 1100 for power supply power sharing adjustment in an information processing system that includes the ability to identify the fan that has failed when it is detected. Process 1100 may be used as part of process 1000 described in FIG. 10 or part of a different process for power supply power sharing. In block 1110, the fan from the set of fans 120 that has failed (e.g., in block 110 of process 1000) is identified. The fan may be identified based on a specific fan identification number that is included with data for the fan. For example, the fan may be identified using a location value with respect to other components in the information processing system 1100, such as one or more of the power supplies 110.

In block 1120, the power supply or power supplies that is/are being cooled by the failed fan identified in block 1110 is identified. The power supplies may be identified based on a listing or table of entries associating each one of the power supplies 110 with one or more of the fans 120. In another example, the power supplies may additionally or alternatively be identified by determining the power supply or power supplies to which the failed fan provides cooling in a normal operating state. The determination may use location information or a listing or table of entries similar to that described above.

In block 1130, the electrical energy supplied by the power supply or power supplies identified in block 1120 is adjusted to be less than the electrical energy supplied by each of the remainder of the power supplies. The adjustment may be determined using a specific listing or table of power sharing ratios based on the identified fan and the identified power supply associated with the identified fan. In some examples, a formula may be used to determine the power sharing ratio, with the identified power supply listed as the first or left entry in the ratio. An example formula is shown as:

$$Adjusted Power Sharing Ratio = ( ( P - 1 ) / ( N - 1 ) ) : ( P / ( N - 1 ) ) \qquad ( eq . 2 )$$

where:
N is the total number of fans
P is the number of fans used to cool each of the power supplies in normal operating mode
N>P>2

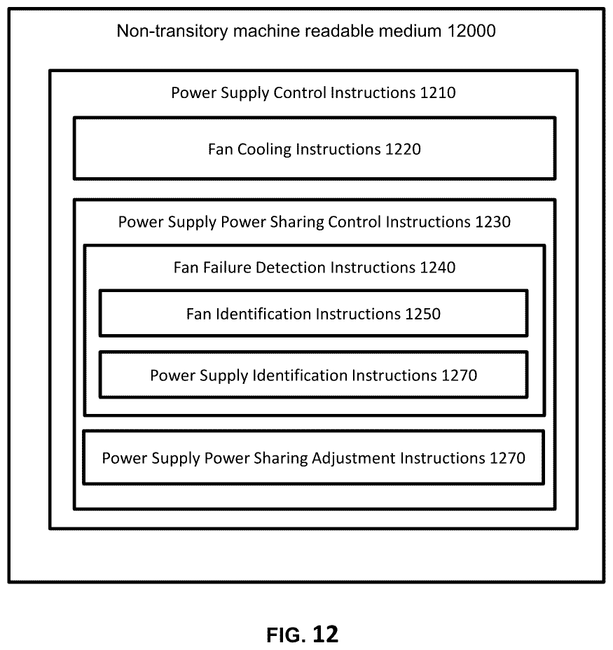

FIG. 12 illustrates example processor executable instructions stored on a non-transitory machine readable medium 12000. In particular, the power supply power control instructions 1210 associated with the controller 130 in information processing system 100 are stored on the medium 12000.

The power supply control instructions 1210 may include instructions that, when executed, instantiate the controller 130 information processing system 100. In particular, the power supply control 1210 may include instructions to perform any or all of the operations that were described above as being performed by the information processing system 100, including for example, any of the example operations illustrated in FIGS. 10-11.

For example, the power supply control instructions 1210 may include fan cooling instructions 1220, and power supply power sharing control instructions 1230 in order to perform the operations in FIG. 10. The power supply power sharing control instructions 1230 may include fan failure detection instructions 1240 may include instructions and the power supply power sharing adjustment instructions 1270 to perform the operations in FIG. 11.

For example, the fan failure detection instructions 1240 may include fan failure identification instructions 1250 and power supply identification instructions 1260. The power supply power sharing adjustment instructions 1240 may include instructions to identify the power supply or power supplies that is/are being cooled by the fan that has been identified in the fan failure instructions 1230. The power supply power sharing adjustment instructions 1240 may further include instructions to adjust the electrical energy supplied by the power supply or power supplies to be less than the electrical energy supplied by the remaining power supplies.

In the description above, various types of electronic circuitry are described. As used herein, “electronic” is intended to be understood broadly to include all types of circuitry utilizing electricity, including digital and analog circuitry, direct current (DC) and alternating current (AC) circuitry, and circuitry for converting electricity into another form of energy and circuitry for using electricity to perform other functions. In other words, as used herein there is no distinction between “electronic” circuitry and “electrical” circuitry. In some cases, certain electronic circuitry may comprise processing circuitry. Processor or processing circuitry comprises circuitry configured with logic for performing the various operations. The logic of the processing circuitry may comprise dedicated hardware to perform various operations, software (machine readable and/or processor executable instructions) to perform various operations, or any combination thereof. In examples in which the logic comprises software, the processing circuitry may include a processor to execute the software instructions and a memory device that stores the software. The processor may comprise one or more processing devices capable of executing machine readable instructions, such as, for example, a processor, a processor core, a central processing unit (CPU), a controller, a microcontroller, a system-on-chip (SoC), a digital signal processor (DSP), a graphics processing unit (GPU), etc. In cases in which the processing circuitry includes dedicated hardware, in addition to or in lieu of the processor, the dedicated hardware may include any electronic device that is configured to perform specific operations, such as an Application Specific Integrated Circuit (ASIC), a Field Programmable Gate Array (FPGA), a Complex Programmable Logic Device (CPLD), discrete logic circuits, a hardware accelerator, a hardware encoder, etc. The processing circuitry may also include any combination of dedicated hardware and processor plus software.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

Further, spatial, positional, and relational terminology used herein is chosen to aid the reader in understanding examples of the implementations but is not intended to limit the implementation to a particular reference frame, orientation, or positional relationship. For example, spatial, positional, and relational terms such as “up”, “down”, “lateral”, “beneath”, “below”, “lower”, “above”, “upper”, “proximal”, “distal”, and the like may be used herein to describe directions or to describe one element's or feature's spatial relationship to another element or feature as illustrated in the figures. These spatial terms are used relative to reference frames in the figures and are not limited to a particular reference frame in the real world. Thus, for example, the direction “up” in the figures does not necessarily correspond to an “up” in a world reference frame (e.g., away from the Earth's surface). Furthermore, if a different reference frame is considered than the one illustrated in the figures, then the spatial terms used herein may need to be interpreted differently in that different reference frame. For example, the direction referred to as “up” in relation to one of the figures may correspond to a direction that is called “down” in relation to a different reference frame that is rotated 180 degrees from the figure's reference frame. As another example, if a device is turned over 180 degrees in a world reference frame as compared to how it was illustrated in the figures, then an item described herein as being “above” or “over” a second item in relation to the Figures would be “below” or “beneath” the second item in relation to the world reference frame. Moreover, the poses of items illustrated in the figure are chosen for convenience of illustration and description, but in an implementation in practice the items may be posed differently.

In addition, the singular forms “a,” “an,” and “the” are intended to include the plural forms as well, unless the context indicates otherwise. Moreover, the terms “comprises,” “comprising,” “includes,” and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

Provide: As used herein, to “provide” an item means to have possession of and/or control over the item. This may include, for example, forming (or assembling) some or all of the item from its constituent materials and/or, obtaining possession of and/or control over an already-formed item.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}.”

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within +1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the implementations disclosed herein. It is intended that the specification and examples be considered as exemplary only, with the following claims being entitled to their fullest breadth, including equivalents, under the applicable law.

What is claimed is:

1. A method comprising:
providing cooling to at least two power supplies in an information processing system, the cooling provided to each of the at least two power supplies by a set of fans, the power supplies supplying electrical energy to an electronic circuit according to a power sharing ratio, the electronic circuit comprising a circuit assembly of the information processing system;
detecting a failure of one of the fans; and
adjusting the power sharing ratio from a default ratio to an adjusted ratio in response to detecting the failure of the one of the fans.

2. The method of claim 1, wherein adjusting the power sharing ratio comprises applying an offset to a characteristic of the power supplies.

3. The method of claim 3, wherein the characteristic is a droop curve associated with the power supplies.

4. The method of claim 1, wherein the power supplies are smart supplies and wherein adjusting the power sharing ratio comprises providing a communication signal to each of the power supplies to adjust an amount of electrical energy supplied.

5. The method of claim 1, wherein the default ratio comprises an equal share for each of the power supplies, and the adjusted ratio corresponds to the proportional distribution of the fans that are not failed amongst the power supplies.

6. The method of claim 1, wherein adjusting the power sharing ratio comprises identifying a given power supply which is associated with the one of the fans that has failed and adjusting the electrical energy provided by the given power supply to be less than the electrical energy supplied by each of the remainder of the power supplies.

7. The method of claim 6, wherein the power supplies are two power supplies, wherein the set of fans are four fans with each of the two power supplies cooled by two of the four fans, and wherein the default ratio is 50:50 and the adjusted ratio is 33:67.

8. The method of claim 5, wherein the power supplies are two power supplies, the default ratio is 50:50, and the adjusted ratio is A/C: B/C, wherein A is the number of non-failed fans cooling the given power supply, B is the number of non-failed fans cooling the other power supply of the two power supplies, and C is the total number of non-failed fans.

9. The method of claim 1, wherein the fans provide cooling to each of the power supplies by generating a flow of air over components included in each of the power supplies.

10. The method of claim 1, wherein adjusting the proportion of the electrical energy supplied by each of the power supplies is performed by control circuitry coupled to the primary circuit assembly.

11. The method of claim 1, wherein detecting if one of the fans providing cooling to the power supplies has failed comprises at least one of determining whether a rotational speed for the one of the fans is less than a programmed rotational speed by more than a threshold value, determining whether one of the fans returns an error signal, determining whether the one of fans does return an expected status signal, and determining whether one of the fans is not drawing current when a voltage is applied.

12. An information processing system comprising:
an electronic circuit comprising a primary circuit board of the information processing system;
at least two power supplies, each power supply providing electrical energy to the electronic circuit according to a power sharing ratio, each power supply being cooled by a set of fans; and
a controller, coupled to the set of power supplies and the set of fans, the controller detecting a failure of one of the fans and adjusting the power sharing ratio from a default ratio to an adjusted ratio in response to detecting the failure of the one of the fans.

13. The information processing system of claim 12, wherein the controller adjusts the power sharing ratio by applying an offset to a characteristic of the at least two power supplies.

14. The information processing system of claim 12, wherein the controller further identifies a given power supply which is associated with the one of the fans that has failed and adjusts the electrical energy provided by the given power supply to be less than the electrical energy supplied by each of the remainder of the power supplies.

15. The information processing system of claim 14, wherein the power supplies are two power supplies, wherein the set of fans are four fans with each of the two power supplies cooled by two of the four fans, and wherein the default ratio is 50:50 and the adjusted ratio is 33:67.

16. The information processing system of claim 12, wherein the fans provide cooling to each of the power supplies by generating a flow of air over components included in each of the power supplies.

17. The information processing system of claim 12, wherein the information processing system comprises at least one of a network switch and a server.

18. The information processing system of claim 12, wherein the controller detects if one of the fans providing cooling to the power supplies has failed by at least one of determining at least one of whether a rotational speed for the one of the fans is less than a programmed rotational speed by more than a threshold value, determining whether one of the fans returns an error signal, determining whether the one of fans does return an expected status signal, and determining whether one of the fans is not drawing electric current.

19. A non-transitory machine readable medium storing an operating image comprising instructions that, when executed by at least one processor in an information processing system, causes the system to:
detect a failure of one of a set of fans, the set of fans providing cooling for at least two power supplies supplying electrical energy to an electronic circuit according to a power sharing ratio, the electronic circuit comprising a primary circuit for the information processing system; and
adjust the power sharing ratio from a default ratio to an adjusted ratio in response to detecting the failure of the one of the fans.

20. The non-transitory machine readable medium of claim 19, wherein adjusting the power sharing ratio comprises identifying a given power supply of the at least two power supplies which is associated with the one of the fans that has failed and adjusting the electrical energy provided by the given power supply to be less than the electrical energy supplied by each of the remainder of the at least two power supplies.
